(19) United States
(12) Patent Application Publication
(10) Pub. No.: US 2013/0258630 A1
(43) Pub. Date: Oct. 3, 2013

(54) HARD DISK DRIVE CONNECTOR

(71) Applicants: BO TIAN, Shenzhen City (CN); KANG WU, Shenzhen City (CN)

(72) Inventors: BO TIAN, Shenzhen City (CN); KANG WU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/597,286

(22) Filed: Aug. 29, 2012

(30) Foreign Application Priority Data
Mar. 29, 2012 (CN) 201210087695.2

(51) Int. Cl. H05K 7/00

(52) U.S. Cl. 361/785

(57) ABSTRACT

A hard disk drive (HDD) connector includes a motherboard port, a HDD port, and a signal processing circuit. The motherboard port and the HDD port are connected to a motherboard and a HDD, respectively. The signal processing circuit includes a signal processing module. The signal processing module is connected between the motherboard port and the HDD port to enhance signal transmission integrity between the motherboard and the HDD.

### BACKGROUND

1. Technical Field

The disclosure relates to a hard disk drive (HDD) connector.

2. Description of the Related Art

A motherboard can have more than two central processing units (CPUs) and corresponding peripheral components positioned on the motherboard, which will lead to an increase in size of the motherboard. In this way, a longer transmission line is also needed between a HDD port and a motherboard port setting on the motherboard, which may affect transmission integrity of a high speed signal, such as a serial attached SCSI (SAS) signal or a serial advanced technology attachment (SATA) signal, for example.

Therefore, there is room for improvement within the art.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views. Wherever possible, the same reference numbers are used throughout the drawings to refer to the same or like elements of an embodiment.

FIG. 1 is a block diagram of a HDD connector, according to an exemplary embodiment, and showing the HDD connector connected between a HDD and a motherboard.

FIG. 2 is a schematic diagram of the HDD connector shown in FIG. 1.

FIG. 3 is a partial circuit diagram of the HDD connector shown in FIG. 2.

FIG. 4 is a circuit diagram showing a HDD port directly connected to a motherboard port, without the HDD connector shown in FIG. 1.

### DETAILED DESCRIPTION

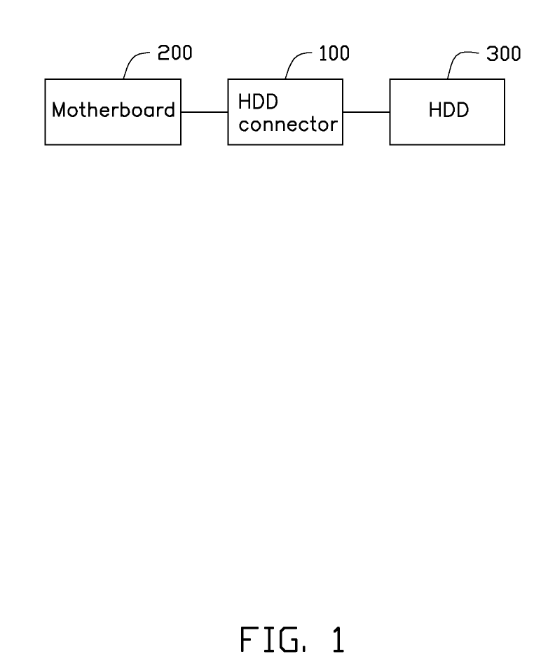

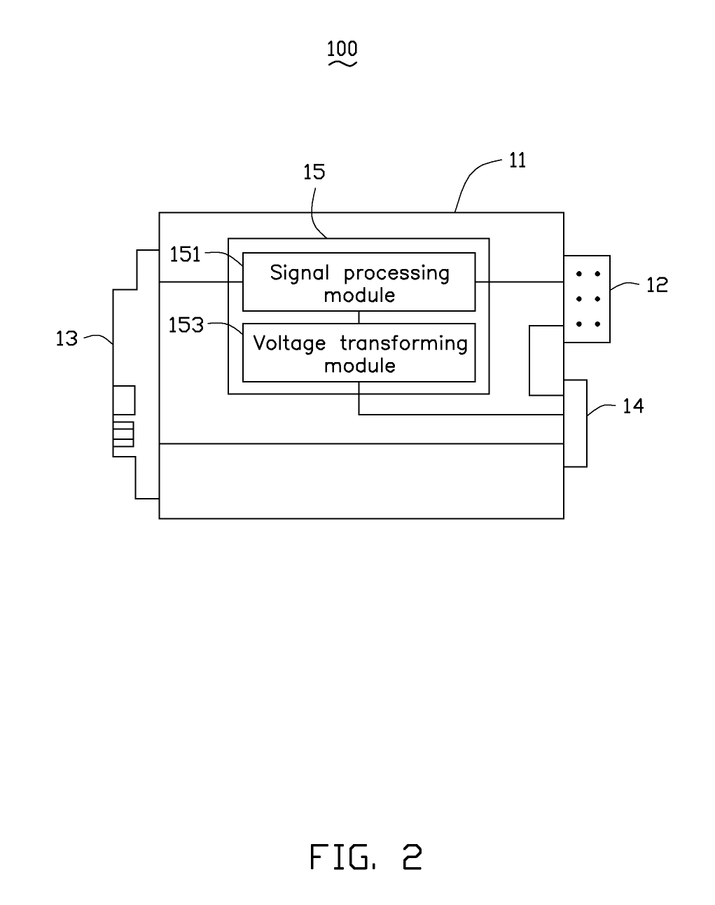

FIG. 1 is a block diagram of a HDD connector 100, according to an exemplary embodiment. The HDD connector 100 is connected between a motherboard 200 and a HDD 300 and is configured to enhance signal transmission integrity between the motherboard 200 and the HDD 300. Referring to FIG. 2, the HDD connector 100 includes a housing 11, a motherboard port 12, a HDD port 13, a power port 14, and a signal processing circuit 15.

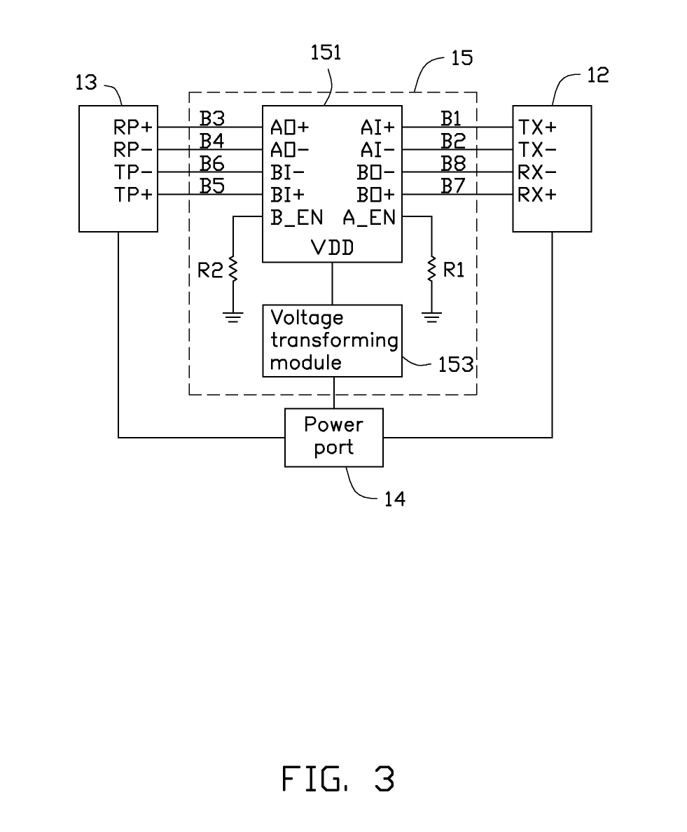

The motherboard port 12 is mounted on a first side (e.g., a right side) of the housing 11 and is configured to connect to the motherboard 200. Referring to FIG. 3, the motherboard port 12 includes a group of signal transmitting terminals TX+, TX− and a group of signal receiving terminals RX+, RX−.

The HDD port 13 is mounted on a second side (e.g., a left side) opposite to the first side of the housing 11 and is configured to connect to the HDD 300. In one embodiment, the HDD port 13 may be a serial attached SCSI (SAS) port that supports both SAS HDDs and serial advanced technology attachment (SATA) HDDs. The HDD port 13 includes a group of signal transmitting pins TP+, TP− and a group of signal receiving pins RP+, RP−.

The power port 14 is mounted on the first side of the housing 11 adjacent to the motherboard port 12. The power port 14 is electronically connected to the motherboard port 12 and thereby connected to a power supply (not shown) of the motherboard 200 through the motherboard port 12. The power port 14 is also electronically connected to the HDD port 13 and provides power from the power supply to the HDD 300 through the HDD port 13.

The signal processing circuit 15 is mounted in an inner of the housing 11 and is electronically connected between the motherboard port 12 and the HDD port 13. In this way, the motherboard 200 exchanges SAS signal or SATA signal with the HDD 300 through the signal processing circuit 15. In detail, the signal processing circuit 15 includes a signal processing module 151 and a voltage transforming module 153. In one embodiment, the signal processing module 151 may be a PI3EQX6701 re-drive chip and includes a group of A-channel inputs AI+, Al−, a group of A-channel outputs AO+, AO−, an A-channel enabled terminal A-EN, a group of B-channel inputs BI+, BI−, a group of B-channel outputs BO+, BO−, a B-channel enabled terminal B-EN, and a power terminal VDD. The group of A-channel inputs AI+, AI− is respectively connected to the signal transmitting terminals TX+, TX− of the motherboard port 12 through a group of transmission lines B1, B2. The group of A-channel outputs AO+, AO− is respectively connected to the signal receiving pins RP+, RP− through a group of transmission lines B3, B4. The A-channel enabled terminal A-EN is connected to ground through a first resistor R1. In this way, the motherboard 200 can transmit the SAS signal or the SATA signal to the HDD 300 through the A-channel inputs AI+, AI− and the A-channel outputs AO+, AO− (i.e., A-channel of the signal processing module 151), i.e., communicates with the HDD 300.

Similarly, the group of B-channel inputs BI+, BI− is respectively connected to the signal transmitting pins TP+, TP− of the HDD port 13 through a group of transmission lines B5, B6. The group of B-channel outputs BO+, BO− is respectively connected to the signal receiving terminals RX+, RX− of the motherboard port 12 through a group of transmission lines B7, B8. The B-channel enabled terminal B-EN is connected to ground through a second resistor R2. In this way, the HDD 300 can transmit the SAS signal or the SATA signal to the motherboard 200 through the B− channel inputs BI+, BI− and the B-channel outputs BO+, BO− (i.e., B-channel of the signal processing module 151), i.e., communicates with the motherboard 200.

A first terminal of the voltage transforming module 153 is connected to the power port 14. A second terminal of the voltage transforming module 153 is connected to the power terminal VDD. The voltage transforming module 153 may be a voltage regulator-down (VRD) or a voltage dividing circuit. The voltage transforming module 153 receives power from the power supply of the motherboard 200 through the power port 14 and transforms the received power into a voltage equal to a working voltage of the signal processing module 151 to start the signal processing module 151.

In use, the signal processing circuit 15 is received in the housing 11 and establishes connection with the motherboard port 12 and the HDD port 13 of the HDD connector 100. Then, the HDD connector 100 is electronically connected to a motherboard 200 through the motherboard port 12 and also electronically connected to a HDD 300 through the HDD port 13. When the motherboard 200 exchanges the SAS signal or the SATA signal with the HDD 300, a length of signal transmission lines between the motherboard port 12 and the HDD port 13 determines signal integrity. In detail, when a length of signal transmission lines between the motherboard port 12 and the HDD port 13 is longer, a capacitive resistance of the signal transmission lines is greater and thereby signal transmission integrity of the SAS signal or the SATA signal is degraded. Correspondingly, a length of signal transmission lines between the motherboard port 12 and the HDD port 13 is shorter, a capacitive resistance of the signal transmission lines is lower and thereby signal integrity of the SAS signal or the SATA signal is better.

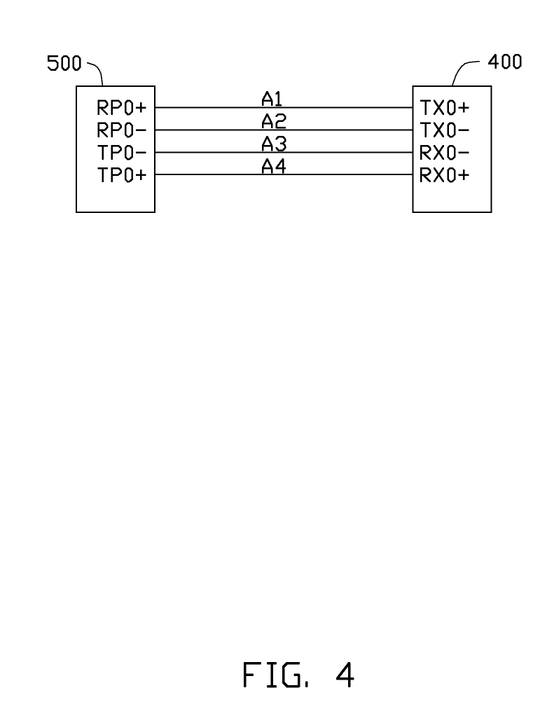

Thus, when the motherboard port 12 connects to the signal processing circuit 15 through the group of transmission lines B1, B2, B7, and B8, and the HDD port 13 connects to the signal processing circuit 15 through the group of transmission lines B3, B4, B5, and B6, a total length of the transmission lines is about B=B1+B2+B3+B4+B5+B6+B7+B8. Referring to FIG. 4, similarly, when a motherboard port 400 directly connects to a HDD port 500 through a group of transmission lines A1, A2, A3, and A4, a total length of the transmission lines is about A=A1+A2+A3+A4.

Total length of transmission line B is lower than total length of transmission line A. Correspondingly, a capacitive load generated by the transmission line B is lower than a capacitive load generated by the transmission line A. In this way, when the motherboard 200 exchanges the SAS signal or the SATA signal with the HDD 300 through the signal processing circuit 15, the length of the transmission lines can be effectively decreased, thereby reducing a capacitive load generated by the transmission lines, and enhancing transmission integrity of the SAS signal or the SATA signal.

Accordingly, the HDD connector 100 has a simple structure and does not need an increasingly complicated trace layout on the motherboard 200. Thereby reducing a design difficulty of the motherboard 200 effectively, simplifying and decreasing a transmission path of the SAS signal or the SATA signal, and improving signal transmission integrity of the SAS signal or the SATA signal.

In the present specification and claims, the word “a” or “an” preceding an element does not exclude the presence of a plurality of such elements. Further, the word “comprising” does not exclude the presence of elements or steps other than those listed.

It is to be also understood that even though numerous characteristics and advantages of exemplary embodiments have been set forth in the foregoing description, together with details of the structures and functions of the embodiments, the disclosure is illustrative only, and changes may be made in detail, especially in matters of arrangement of parts within the principles of this disclosure to the full extent indicated by the broad general meaning of the terms in which the appended claims are expressed.

What is claimed is:

1. A hard disk drive (HDD) connector, comprising:
a motherboard port connected to a motherboard;
a HDD port connected to a HDD; and
a signal processing circuit comprising a signal processing module; wherein the motherboard port is electronically connected to the HDD port through the signal processing module.

2. The HDD connector of claim 1, wherein the HDD port is a serial attached SCSI port.

3. The HDD connector of claim 1, further comprising a housing, wherein the motherboard port and the HDD port are mounted on a surface of the housing and the signal processing circuit is mounted in an inside of the housing.

4. The HDD connector of claim 1, further comprising a power port, wherein the power port is connected to the motherboard port and receives power from a power supply of the motherboard, the power port is also connected to the HDD port to output the received power to the HDD through the HDD port.

5. The HDD connector of claim 4, wherein the signal processing circuit comprises a voltage transforming module, the signal processing module comprises a power terminal, a first terminal of the voltage transforming module is connected to the power terminal, a second terminal of the voltage transforming module is connected to the power port, the voltage transforming module receives the power from the power supply and transforms the received power into a voltage equal to a working voltage of the signal processing module to start the signal processing module.

6. The HDD connector of claim 5, wherein the signal transforming module is a voltage regulator-down.

7. The HDD connector of claim 5, wherein the signal transforming module is a voltage dividing circuit.

8. The HDD connector of claim 1, wherein the signal processing module comprises a group of A-channel inputs and a group of B-channel outputs; the motherboard port comprises a group of signal transmitting terminals and a group signal receiving terminals; the group of signal transmitting terminals are connected to the group of A-channel inputs through a group transmission lines and the group of signal receiving terminals are connected to the group of B-channel outputs through a group transmission lines.

9. The HDD connector of claim 1, wherein the signal processing module comprises a group of A-channel outputs and a group of B-channel inputs; the HDD port comprises a group of signal transmitting pins and a group of signal receiving pins; the group of signal transmitting pins are connected to the group of B-channel inputs through a group transmission lines and the group of signal receiving pins are connected to the group of A-channel outputs through a group transmission lines.

10. The HDD connector of claim 1, wherein the signal processing module comprising an A-channel enabled terminal connected to ground through a first resistor.

11. The HDD connector of claim 1, wherein the signal processing module comprising a B-channel enabled terminal connected to ground through a second resistor.

12. A hard disk drive (HDD) connector, comprising:
a housing;
a motherboard port mounted on a first side of the housing and connected to a motherboard;
a HDD port mounted on a second side opposite to the first side of the housing and connected to a HDD;
a power port mounted on the first side of the housing adjacent to the motherboard port, the power port connected between the motherboard port and the HDD port, the power port receiving power from a power supply of the motherboard through the motherboard port and outputting the received power to the HDD through the HDD port; and
a signal processing circuit mounted in an inner of the housing, wherein signal processing circuit is connected between the motherboard port and the HDD port.

13. The HDD connector of claim 12, wherein the signal processing circuit comprises a voltage transforming module, the signal processing module comprises a power terminal, a first terminal of the voltage transforming module is connected to the power terminal, a second terminal of the voltage transforming module is connected to the power port, the voltage transforming module receives the power from the power supply and transforms the received power into a voltage equal to a working voltage of the signal processing module to start the signal processing module.

14. The HDD connector of claim 12, wherein the signal processing module comprises a group of A-channel inputs and a group of B-channel outputs; the motherboard port comprises a group of signal transmitting terminals and a group signal receiving terminals; the group of signal transmitting terminals are connected to the group of A-channel inputs through a group transmission lines and the group of signal receiving terminals are connected to the group of B-channel outputs through a group transmission lines.

15. The HDD connector of claim 12, wherein the signal processing module comprises a group of A-channel outputs and a group of B-channel inputs; the HDD port comprises a group of signal transmitting pins and a group of signal receiving pins; the group of signal transmitting pins are connected to the group of B-channel inputs through a group transmission lines and the group of signal receiving pins are connected to the group of A-channel outputs through a group transmission lines.

16. The HDD connector of claim 12, wherein the signal processing module comprising an A-channel enabled terminal connected to ground through a first resistor.

17. The HDD connector of claim 12, wherein the signal processing module comprising a B-channel enabled terminal connected to ground through a second resistor.
